(19) United States
(12) Patent Application Publication
(10) Pub. No.: US 2026/0206621 A1
(43) Pub. Date: Jul. 16, 2026

(54) SIDE-BY-SIDE DIE INTERCONNECTION

(71) Applicant: QUALCOMM Incorporated, San Diego, CA (US)

(72) Inventors: Aniket PATIL, San Diego, CA (US); Hong Bok WE, San Diego, CA (US); Yangyang SUN, San Diego, CA (US)

(21) Appl. No.: 19/018,131

(22) Filed: Jan. 13, 2025

(51) Int. Cl. H01L 23/538; H01L 23/373; H01L 23/498

(52) U.S. Cl. CPC H10W 70/65; H10W 40/253; H10W 40/258; H10W 70/611; H10W 70/635; H10W 90/701

(57) ABSTRACT

A device includes a plurality of contacts on a first side. The device also includes first interconnect conductors along a first edge of the die, and second interconnect conductors external to the die and along a second edge of the die. The device further includes redistribution layers coupled to a second side of the die, where the redistribution layers define a plurality of pairs of conductive paths between the first interconnect conductors and the second interconnect conductors.

### FIELD

Various features relate to side-by-side interconnection of integrated circuit dies.

### BACKGROUND

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art electronic devices generally demand a small form factor, low cost, a tight power budget, and high electrical performance. Integrated device package design has evolved in an attempt to meet these various goals; however, these goals are often in conflict with one another. For example, smaller integrated device packages may be more expensive to manufacture and provide less space for routing conductive paths between dies and/or other components of the integrated device package, which can limit electrical performance. One approach to address many of these goals is to use a package-on-package (PoP) configuration; however, PoP configurations can introduce other concerns, such as heat management.

### SUMMARY

Various features relate to a device that includes a die that includes a plurality of contacts on a first side. The device also includes first interconnect conductors along a first edge of the die, and second interconnect conductors external to the die and along a second edge of the die. The device further includes redistribution layers coupled to a second side of the die, where the redistribution layers define a plurality of pairs of conductive paths between the first interconnect conductors and the second interconnect conductors.

One example provides a side-by-side integrated device package that includes a package substrate and a first die electrically coupled, on a first side of the first die, to a first set of contacts of the package substrate. The side-by-side integrated device package also includes a second die electrically coupled to a second set of contacts of the package substrate. The side-by-side integrated device package further includes a mold compound that at least partially encapsulates the first die. The side-by-side integrated device package also includes first interconnect conductors along a first edge of the first die. The side-by-side integrated device package further includes second interconnect conductors external to the first die and along a second edge of the first die. The side-by-side integrated device package also includes redistribution layers coupled to a second side of the first die, where the redistribution layers define a plurality of pairs of conductive paths between the first interconnect conductors and the second interconnect conductors.

Another example provides a method for fabricating a device. The method includes coupling a second side of a die to a set of redistribution layers such that a first side of the die that includes contacts of the die faces away from the redistribution layers. The method also includes electrically coupling first interconnect conductors to the redistribution layers along a first edge of the die. The method further includes electrically coupling second interconnect conductors to the redistribution layers along a second edge of the die and external to the die, where the redistribution layers define a plurality of pairs of conductive paths between the first interconnect conductors and the second interconnect conductors.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a schematic cross-sectional profile view of an example of an integrated device package that includes two or more dies electrically interconnected to one another in a side-by-side arrangement.

FIG. 1B illustrates a schematic top view of a portion of an interconnect structure of the integrated device package of FIG. 1A.

FIG. 2 illustrates a schematic cross-sectional profile view of an example of the integrated device package of FIG. 1A.

FIG. 3 illustrates a schematic cross-sectional profile view of another example of the integrated device package of FIG. 1A.

FIG. 4 illustrates a schematic cross-sectional profile view of another example of the integrated device package of FIG. 1A.

FIG. 5 illustrates a schematic cross-sectional profile view of another example of the integrated device package of FIG. 1A.

FIG. 6A illustrates a first portion of a first exemplary sequence for fabricating a device that includes a die and structure for routing connections along a back side of the die.

FIG. 6B illustrates a second portion of the exemplary sequence of FIG. 6A.

FIG. 6C illustrates a third portion of the exemplary sequence of FIG. 6A.

FIG. 7A illustrates a first portion of a second exemplary sequence for fabricating a device that includes a die and structure for routing connections along a back side of the die.

FIG. 7B illustrates a second portion of the exemplary sequence of FIG. 7A.

FIG. 7C illustrates a third portion of the exemplary sequence of FIG. 7A.

FIG. 8A illustrates a first portion of a third exemplary sequence for fabricating a device that includes a die and structure for routing connections along a back side of the die.

FIG. 8B illustrates a second portion of the exemplary sequence of FIG. 8A.

FIG. 8C illustrates a third portion of the exemplary sequence of FIG. 8A.

FIG. 9A illustrates a first portion of an exemplary sequence for fabricating an integrated device package that includes two or more dies electrically interconnected to one another in a side-by-side arrangement.

FIG. 9B illustrates a second portion of the exemplary sequence of FIG. 9A.

FIG. 10 illustrates an exemplary flow diagram of a method for fabricating an integrated device package that includes two or more dies electrically interconnected to one another in a side-by-side arrangement.

FIG. 11 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art electronic device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middleof-line (MOL) interconnect layers, which interconnect to the FEOL active devices of an IC.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Aspects of the present disclosure are directed to an integrated device package that is configured to address challenges of routing of connections between dies in a side-by-side arrangement. In the disclosed implementations, some of the connections are routed over one of the dies rather than under or around the die within a package substrate. Routing some connections over a die rather than through the package substrate enables using a smaller area of the package substrate for routing the conductive paths between dies, and can also enable using a package substrate with fewer metal layers, thereby reducing the cost and thickness of the package substrate. Additionally, in some cases connections routed over a die can have shorter end-to-end lengths than connections routed through the package substrate, which can improve signal integrity.

### Exemplary Integrated Device Package

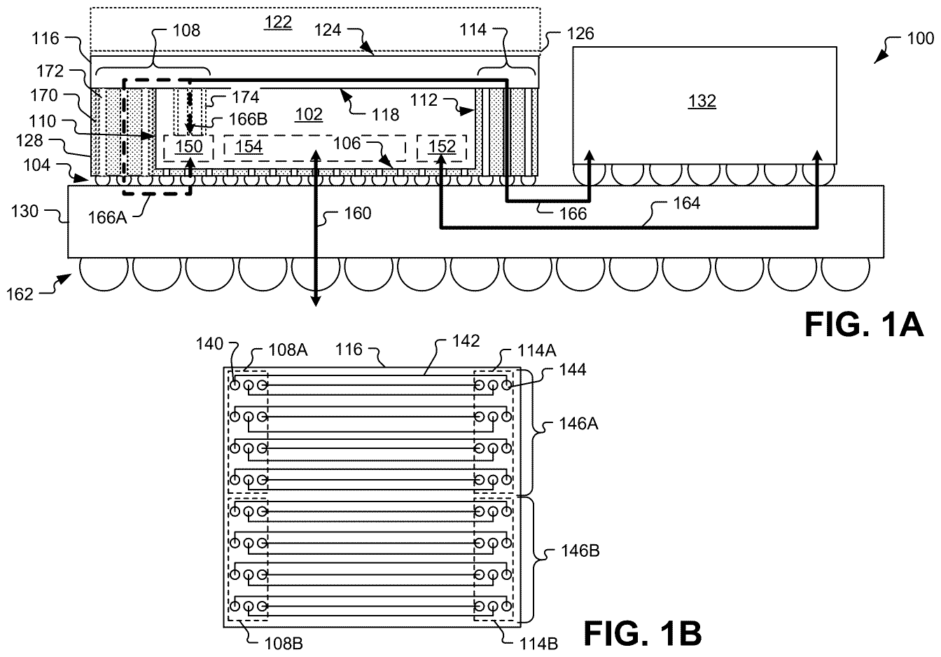

FIG. 1A illustrates a schematic cross-sectional profile view of an example of an integrated device package 100 that includes two or more dies electrically interconnected to one another in a side-by-side arrangement. FIG. 1B illustrates a schematic top view of a portion of an interconnect structure of the integrated device package 100 of FIG. 1A.

Referring to FIG. 1A, the integrated device package 100 includes or corresponds to a side-by-side integrated device package. For example, the integrated device package 100 includes a die 102 and a die 132, which are electrically coupled to one another on a package substrate 130. Optionally, the die 102, the die 132, or both, are at least partially encapsulated within mold compound, which is not shown in FIG. 1A. The die 102 and the die 132 are configured to exchange signals to facilitate operation of the integrated device package 100.

The integrated device package 100 defines conductive paths between the dies 102, 132 to enable exchange of signals. Several examples of conductive paths between the die 102 and the die 132 are illustrated in FIG. 1A. In FIG. 1A, the conductive paths include conductive paths 164 that enable interaction between the die 132 and first circuitry 152 of the die 102 and conductive paths 166 (including conductive paths 166A, conductive paths 166B, or both) that enable interaction between the die 132 and second circuitry 150 of the die 102. As one example, the conductive paths 164 can correspond to or be associated with a first communication channel between the dies 102, 132, and the conductive paths 166 can correspond to or be associated with a second communication channel between the dies 102, 132. In this example, the first circuitry 152 can include hardware interface layer circuitry (also referred to as physical layer interface or PHY circuitry) associated with the first communication channel, and the second circuitry 150 can include hardware interface layer circuitry associated with the second communication channel.

One challenge that can be encountered with design of side-by-side integrated device packages relates to routing of connections between the side-by-side dies (e.g., the dies 102, 132). For example, when one die (e.g., the die 102) is a processor die and the other die (e.g., the die 132) is a memory die, the connections between the dies 102 and 132 can support multiple memory channels which together include many tens or even hundreds of conductors. Design rules specify particular spacing between adjacent conductors for various concerns, such as manufacturing constraints and signal integrity concerns. As a result, providing many tens or hundreds of conductors to interconnect dies in a side-by-side arrangement can significantly increase dimensions (e.g., lateral dimensions, thickness, or both) of the package substrate 130, which is counter to design goals of reducing package size and cost.

The integrated device package 100 addresses the challenge of routing of connections between the dies 102, 132 by routing a portion of some of the connections (e.g., connections associated with the conductive paths 166) over the die 102 rather than under or around the die 102. Routing the connections associated with the conductive paths 166 in this manner provides technical advantages such as using a smaller area (e.g., lateral dimensions) of the package substrate 130 for routing the conductive paths 166 and enabling use of fewer metal layers in the package substrate 130 (thereby reducing the cost and thickness of the package substrate 130). Additionally, in some cases the connections associated with the conductive paths 166 can have shorter end-to-end lengths when routed over the die 102 rather than under or around the die 102, thereby providing signal integrity improvements. Further, an interconnect structure used to route the connections between the package substrate 130 and the top of the die 102 provides an area to support a heat sink that has a larger footprint than the die 102, which can improve thermal management for the die 102.

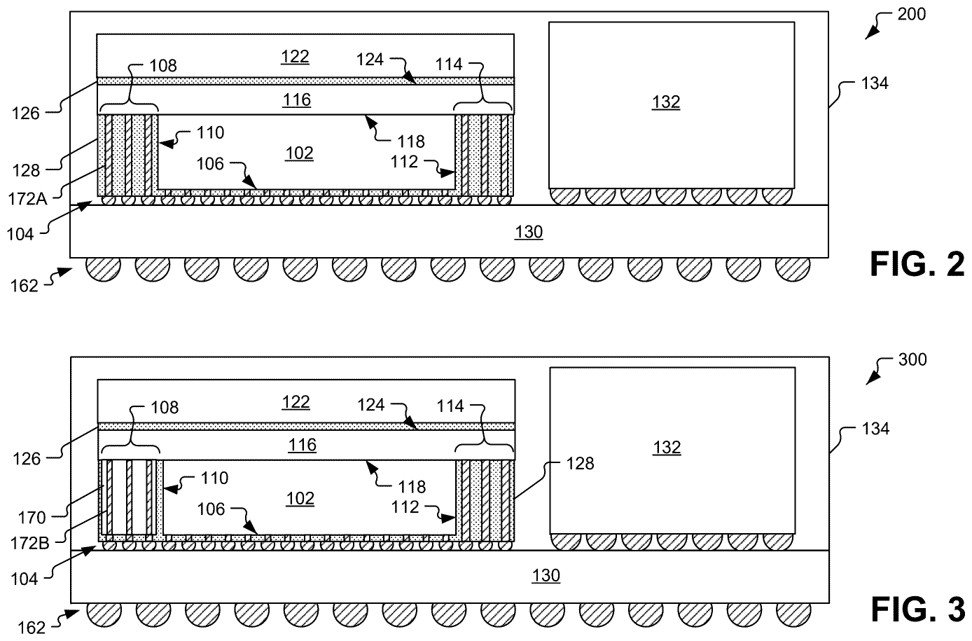

FIG. 1A illustrates several different structures that can be used to route the conductive paths 166. The structures associated with the conductive paths 166 in FIG. 1A can be used individually (as illustrated in described with reference to FIGS. 2-4) or together (as illustrated in FIG. 1A), depending on various factors such as design constraints or cost. In some embodiments, the conductive paths 166 include the conductive paths 166B, which include conductors 174 (e.g., through vias) within the die 102. For example, in such embodiments, the conductors 174 are coupled to the second circuitry 150 within the die 102 and are coupled to or include contacts on a side 118 (e.g., the top in the orientation illustrated in FIG. 1A) of the die 102 opposite the package substrate 130. In some embodiments, the conductive paths 166 include the conductive paths 166A, which include conductors 172 that are external to the die 102. For example, in such embodiments, the conductors 172 can be routed through mold compound 128 that at least partially encapsulates the die 102. As another example, in such embodiments, the conductors 172 can include through vias disposed within another component 170. To illustrate, the component 170 can include another die with through vias corresponding to the conductors 172. Thus, the structures associated with the conductive paths 166 include the conductors 174 within the die 102, the conductors 172 external to the die 102, or both, which are collectively referred to herein as first interconnect conductors 108.

An interconnect structure configured to route the conductive paths 166 over the die 102 includes the first interconnect conductors 108 and second interconnect conductors 114 along a second edge 112 of the die 102. The interconnect structure also includes redistribution layers 116 coupled to the side 118 of the die 102 opposite the package substrate 130. The side 118 of the die 102 to which the redistribution layers 116 are coupled includes or corresponds to a back of the die 102, which can be devoid of contacts in some embodiments. The redistribution layers 116 define a plurality of pairs of conductive paths between the first interconnect conductors 108 and the second interconnect conductors 114. For example, as illustrated in FIG. 1B, a conductor 142 of the redistribution layers 116 forms a conductive path between an interconnect conductor 140 of the first interconnect conductors 108 and an interconnect conductor 144 of the second interconnect conductors 114.

In some embodiments, the first interconnect conductors 108 (or a subset thereof) are external to the die 102. For example, in such embodiments, the first interconnect conductors 108 (or the subset thereof) include the conductors 172. In such embodiments, the conductors 172 are electrically coupled to a first subset of contacts 104 of the package substrate 130. The first subset of the contacts 104 are electrically coupled, through conductors of the package substrate 130, to a second subset of the contacts 104, and the second subset of the contacts 104 are electrically coupled to the second circuitry 150. The second interconnect conductors 114 are electrically coupled to a third subset of the contacts 104 of the package substrate 130. The third subset of the contacts 104 are electrically coupled, through conductors of the package substrate 130, to a fourth subset of the contacts 104, which are electrically coupled to the die 132. Thus, in such embodiments, the conductive paths 166 include the second subset of the contacts 104, a set of conductors of the package substrate 130, the first subset of the contacts 104, the first interconnect conductors 108, conductors of the redistribution layers 116, the second interconnect conductors 114, the third subset of the contacts 104, another set of conductors of the package substrate 130, and the fourth subset of the contacts 104.

In some embodiments, the first interconnect conductors 108 (or a subset thereof) are internal to the die 102. For example, in such embodiments, the first interconnect conductors 108 (or the subset thereof) include the conductors 174. In such embodiments, the conductors 174 are electrically coupled to the second circuitry 150 within the die 102 and to contacts on the side 118 of the die 102. The contacts on the side 118 of the die 102 are electrically coupled, via conductors of the redistribution layers 116, to the second interconnect conductors 114. The second interconnect conductors 114 are electrically coupled to a first subset of the contacts 104 of the package substrate 130. The first subset of the contacts 104 are electrically coupled, through conductors of the package substrate 130, to a second subset of the contacts 104, which are electrically coupled to the die 132. Thus, in such embodiments, the conductive paths 166 include the conductors 174, conductors of the redistribution layers 116, the second interconnect conductors 114, the first subset of the contacts 104, a set of conductors of the package substrate 130, and the second subset of the contacts 104.

In contrast, the conductive paths 164 include a subset of contacts 104 associated with (e.g., electrically coupled to) the first circuitry 152, a set of conductors of the package substrate 130, and the subset of the contacts 104 that are electrically coupled to the die 132. The package substrate 130 also includes off-package contacts 162, at least some of which are coupled to a subset of the contacts 104 of the package substrate 130 by conductive paths 160 formed by conductors of the package substrate 130. For example, the die 102 can include third circuitry 154 that is electrically coupled to the off-package contacts 162 via the conductive paths 160. Optionally, the package substrate 130 can also include conductive paths electrically coupling the die 132 to the off-package contacts 162.

Referring to FIG. 1B, one example of pairwise routing of conductors between the first interconnect conductors 108 and the second interconnect conductors 114 is shown. In the example illustrated in FIG. 1B, a first communication channel 146A is associated with a first subset of first interconnect conductors 108 (where the first subset of first interconnect conductors 108 is indicated with reference number 108A) and a first subset of second interconnect conductors 114 (where the first subset of second interconnect conductors 114 is indicated with reference number 114A). A second communication channel 146B is associated with a second subset of first interconnect conductors 108 (where the second subset of first interconnect conductors 108 is indicated with reference number 108B) and a second subset of second interconnect conductors 114 (where the second subset of second interconnect conductors 114 is indicated with reference number 114B). Although the example illustrated in FIG. 1B shows portions of an interconnect structure to route connections associated with two communication channels, in other examples, the interconnect structure can include conductors configured to route connections associated with more than two or fewer than two (e.g., one) communication channels.

In the example illustrated in FIG. 1A, the first edge 110 (along which the first interconnect conductors 108 are disposed) and the second edge 112 (along which the second interconnect conductors 114 are disposed) are shown as opposite edges of the die 102. In other examples, the first edge 110 and the second edge 112 can be adjacent edges of the die 102. In some examples, the first communication channel 146A is associated with conductors that extend between a first pair of adjacent edges of the die 102, and the second communication channel 146B is associated with conductors that extend between a second pair of adjacent edges of the die 102. In examples in which the interconnect structure supports more than two communication channels, conductors associated with the various communication channels can extend between opposite edges of the die 102, adjacent edges of the die 102, or a combination thereof. As an example, conductors associated with one or more of the communication channels can extend between opposite edges of the die 102, and conductors associated with one or more others of the communication channels can extend between adjacent edges of the die 102.

Conductors of the redistribution layers 116 can use finer line width, closer line spacing, or both, as compared to conductors of the package substrate 130. As a result, less space is used to route the conductive paths 166 through the redistribution layers 116 than would be needed to provide the same number and arrangement of interconnects via conductors of the package substrate 130. Thus, the integrated device package 100 can be smaller (in terms of lateral dimension, thickness, or both) than a side-by-side package using interconnections through the package substrate 130.

Optionally, the integrated device package 100 includes a heat spreader 122 coupled to one or more of the dies 102, 132. For example, in FIG. 1A, a first side 106 of the die 102 is positioned proximate the package substrate 130, and the heat spreader 122 is coupled to a second side 118 of the die 102. For example, in FIG. 1A, the heat spreader 122 is coupled to a side 124 of the redistribution layers 116 opposite the die 102 using a dielectric layer 126, which can function as an adhesive, a thermal interface material, or both. The heat spreader 122 can include, for example, a bulk silicon block, a metal block, or a block of another high-thermal conductivity material. In some cases, a footprint of the heat spreader 122 is larger than a footprint of the die 102, which provides improved thermal management. For example, the heat spreader 122 can be disposed on an interconnect structure that includes the first interconnect conductors 108 through the mold compound 128, the redistribution layers 116, and the second interconnect conductors 114 through the mold compound 128. In this example, the footprint of the heat spreader 122 can be approximately the same as the footprint of the interconnect structure.

Each of the dies 102, 132 can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end of line (FEOL) process may be used to fabricate the integrated circuitry in and/or over the semiconductor substrate.

In some implementations, the die 132 includes a Dynamic Random-Access Memory (DRAM) chip (or chiplet). In this illustrative example, the circuitry 150, 152, and/or 154 of the die 102 can include or correspond to interface circuitry (e.g., serializer/deserializer (SerDes) circuitry, a double data rate (DDR)-type DRAM bus interface circuit, etc.), memory buffers, and/or other circuitry that facilitates interaction between the die 102 and the DRAM (e.g., the die 132 in this example).

Although two dies 102, 132 are shown in FIG. 1A, in other examples, the integrated device package 100 can include more than two dies. Further, in some cases, one or both of the dies 102, 132 of FIG. 1A can include or correspond to a stacked integrated circuit (IC) device that includes two or more chiplets stacked one upon another and electrically interconnected. Using chiplets arranged and interconnected as a stacked IC can provide various benefits as compared to providing the same functional circuitry in one monolithic chip. For example, each chiplet is smaller than a monolithic die including all of the same functional circuit blocks would be. Since yield loss in IC manufacturing tends to increase as the die size increases, using smaller dies can reduce yield loss (i.e., increase yield) of the IC manufacturing process. Another benefit is that the chiplets can be fabricated in different locations and/or by different manufacturers, and in some cases, using different fabrication technologies (e.g., different fabrication technology nodes). As an example, one chiplet can include components (e.g., interconnects, transistors, etc.) that have a first minimum size, and another chiplet can include components (e.g., interconnects, transistors, etc.) that have a second minimum size, where the second minimum size is greater than the first minimum size. In contrast, all of the circuitry of a monolithic die is fabricated using the same fabrication technologies and equipment. As a result, when manufacturing a monolithic die, the entire die may be subject to the tightest manufacturing constraint of the most complex component of the monolithic die. In contrast, when using chiplets, different chiplets can be manufactured using different fabrication technologies (e.g., different fabrication technology nodes), and only the chiplet or chiplets that include the most complex components are subjected to the tightest manufacturing constraints. In this arrangement, chiplets fabricated using less expensive and/or higher yield fabrication technologies can be integrated with chiplets fabricated using more expensive and/or lower yield fabrication technologies. Still further, in some cases, as technology improves, the design of a chiplet can be changed. Chiplet stacking allows such new chiplet designs to be integrated with older chiplet designs to form stacked IC devices, which improves manufacturing flexibility and reduces design costs.

The example illustrated in FIG. 1A shows internal conductors 174 and external conductors 172 (which can be through mold conductors, conductors within another component, or some of each) forming portions of the conductive paths 166. FIGS. 2, 3 and 4 illustrate embodiments with various combinations of the conductors 172, 174 used for the conductive paths 166. Each of FIGS. 2-4 illustrates a cross-sectional profile view of an example of an integrated device package that includes many of the same features as the integrated device package 100 of FIG. 1A. In each of FIGS. 2-4, features that are shared with the integrated device package 100 are labeled with the same reference number as used in FIG. 1A. Such features are structurally and functionally the same as described with reference to FIG. 1A except as noted below.

FIG. 2 illustrates a cross-sectional profile view of an example of an integrated device package 200 in which the first interconnect conductors 108 include or correspond to through mold conductors 172A disposed along the edge 110 of the die 102. The through mold conductors 172A form conductive paths (e.g., portions of the conductive paths 166A) through the mold compound 128 between contacts 104 of the package substrate 130 and the redistribution layers 116. The integrated device package 200 of FIG. 2 also includes optional mold compound 134 at least partially encapsulating the die 132, the die 102, the heat spreader 122, or a combination thereof.

FIG. 3 illustrates a cross-sectional profile view of an example of an integrated device package 300 in which the first interconnect conductors 108 include or correspond to though conductors 172B of the component 170, which is disposed alongside of the die 102 (e.g., on the edge 110). The component 170 can include or correspond to a die formed of a crystalline or a glass material (e.g., a semiconductor). Alternatively, the component 170 can include or correspond to a polymer-based component.

In FIG. 3, the through conductors 172B form conductive paths (e.g., portions of the conductive paths 166A) between contacts 104 of the package substrate 130 and the redistribution layers 116. The integrated device package 300 of FIG. 3 also includes optional mold compound 134 at least partially encapsulating the die 132, the die 102, the heat spreader 122, or a combination thereof.

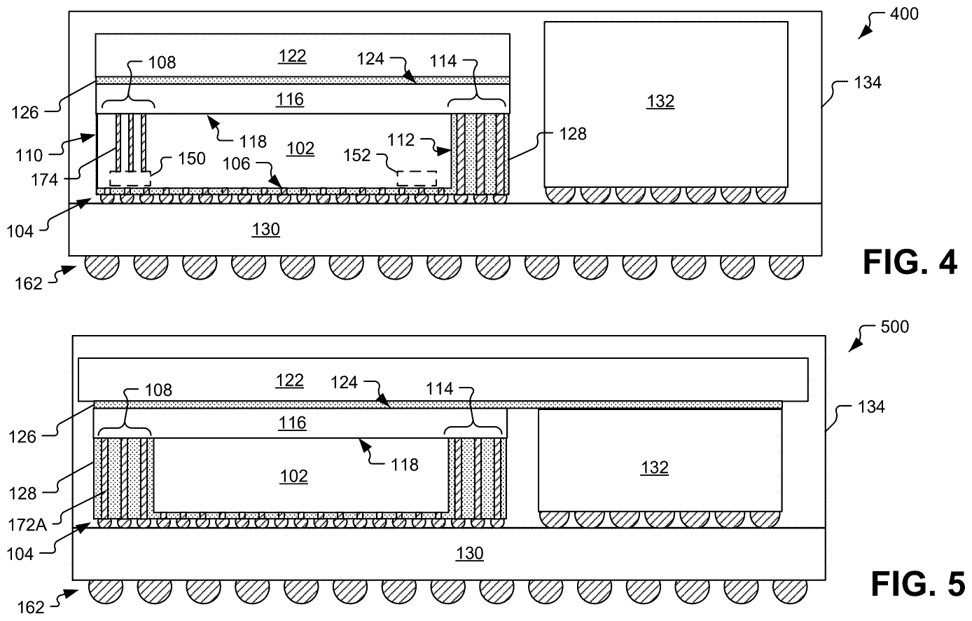

FIG. 4 illustrates a cross-sectional profile view of an example of an integrated device package 400 in which the first interconnect conductors 108 include or correspond to conductors 174 within the die 102. For example, the conductors 174 can be formed using via-last or through-via techniques such that the conductors 174 extend at least from the second circuitry 150 to contacts on the side 118 of the die 102. Thus, in FIG. 4, the conductors 174 form conductive paths (e.g., portions of the conductive paths 166B between the second circuitry 150 and the redistribution layers 116. The integrated device package 400 of FIG. 4 also includes optional mold compound 134 at least partially encapsulating the die 132, the die 102, the heat spreader 122, or a combination thereof.

FIG. 5 illustrates a cross-sectional profile view of an example of an integrated device 500 in which the heat spreader 122 (and optionally the dielectric layer 126) extends beyond the redistribution layers 116. In particular, in the example illustrated in FIG. 5, the heat spreader 122 is disposed over both the die 102 and the die 132. In examples that include more than two dies, the heat spreader 122 can optionally extend over more than two dies.

Although the integrated device package 500 of FIG. 5 illustrates an example in which the first interconnect conductors 108 include or correspond to conductors 172A (similar to the example of FIG. 2), in other examples, the first interconnect conductors 108 of the integrated device package 500 can include the conductors 172B, the conductors 174, or both, instead of or in addition to the conductors 172A.

### Exemplary Sequences for Fabricating Integrated Device Packages

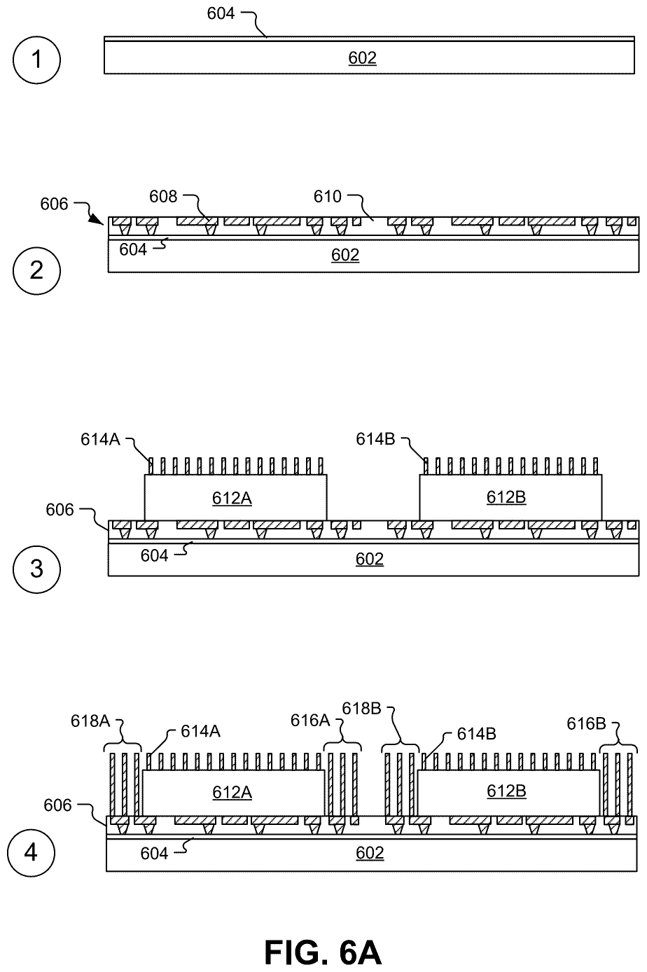

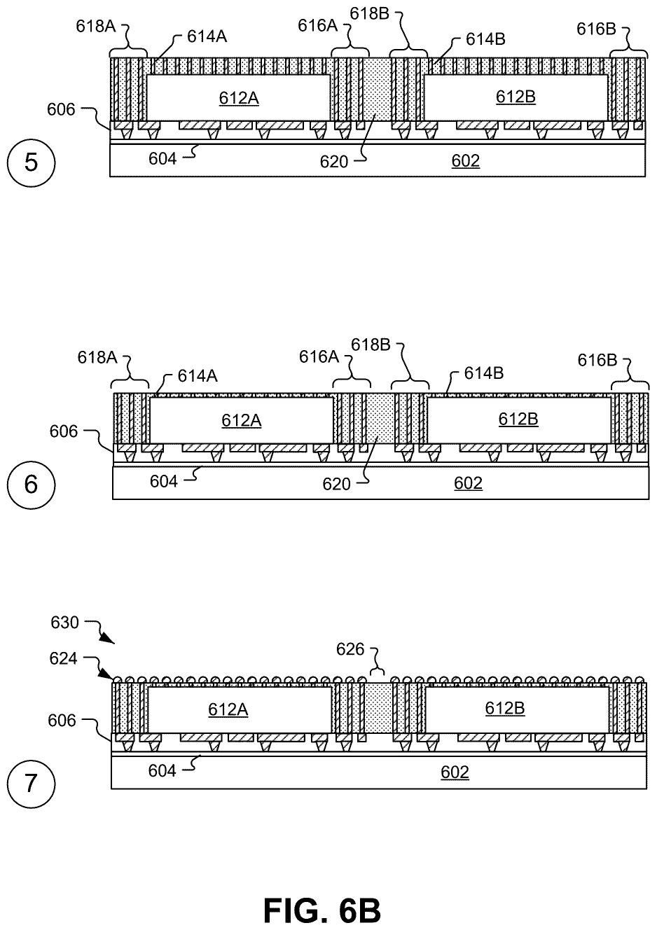

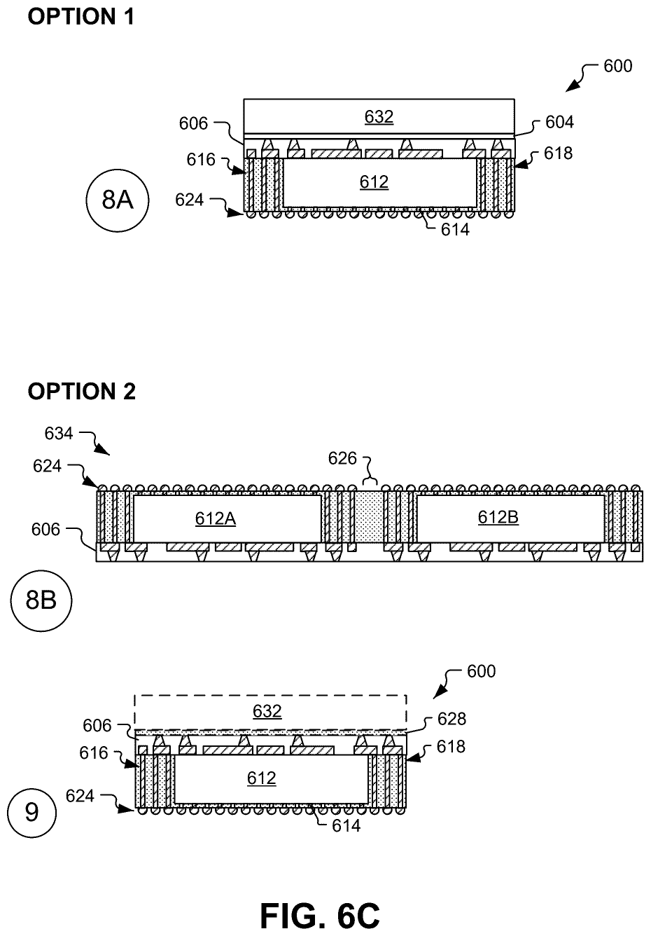

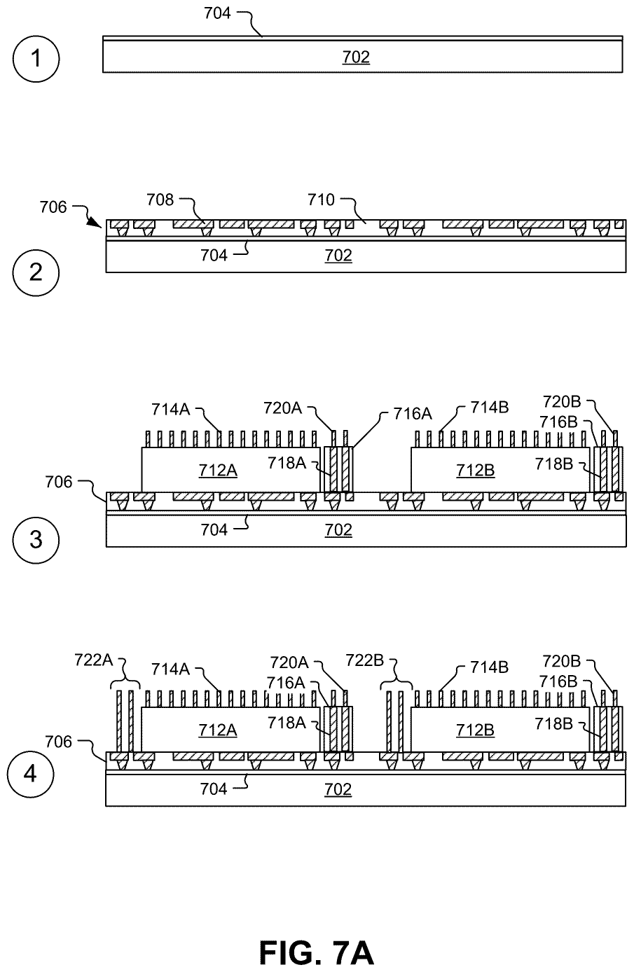

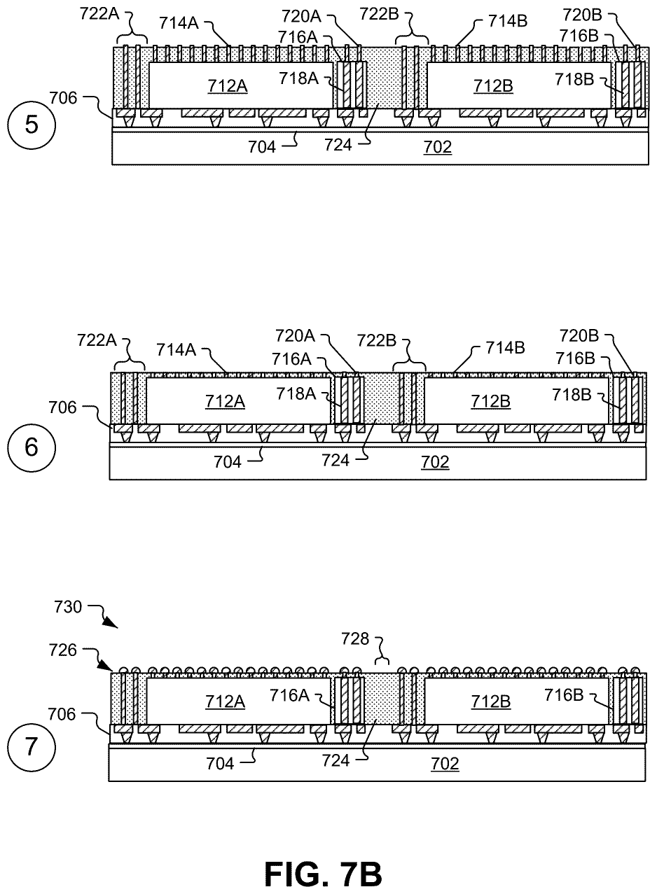

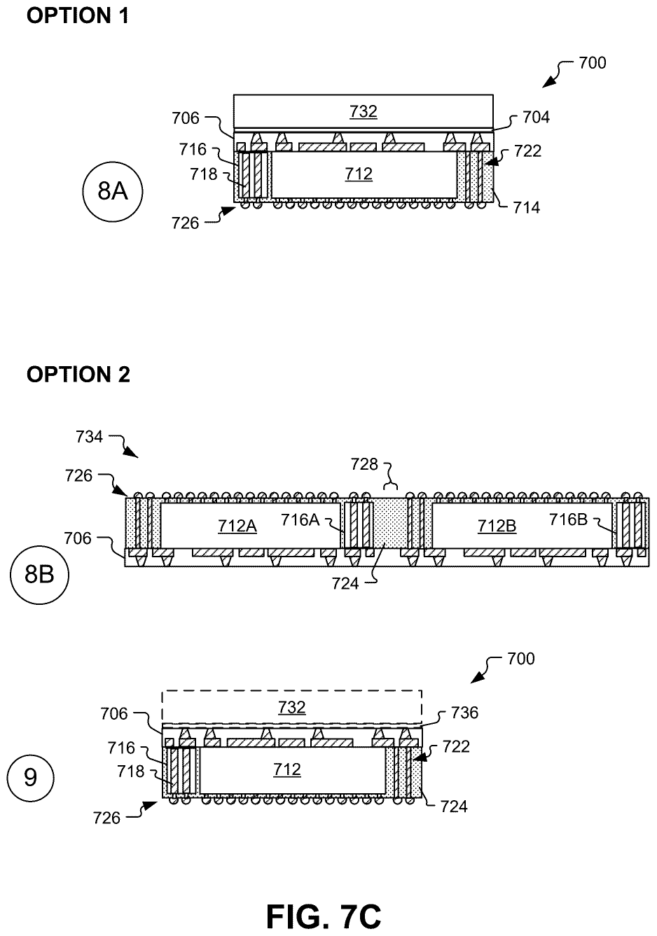

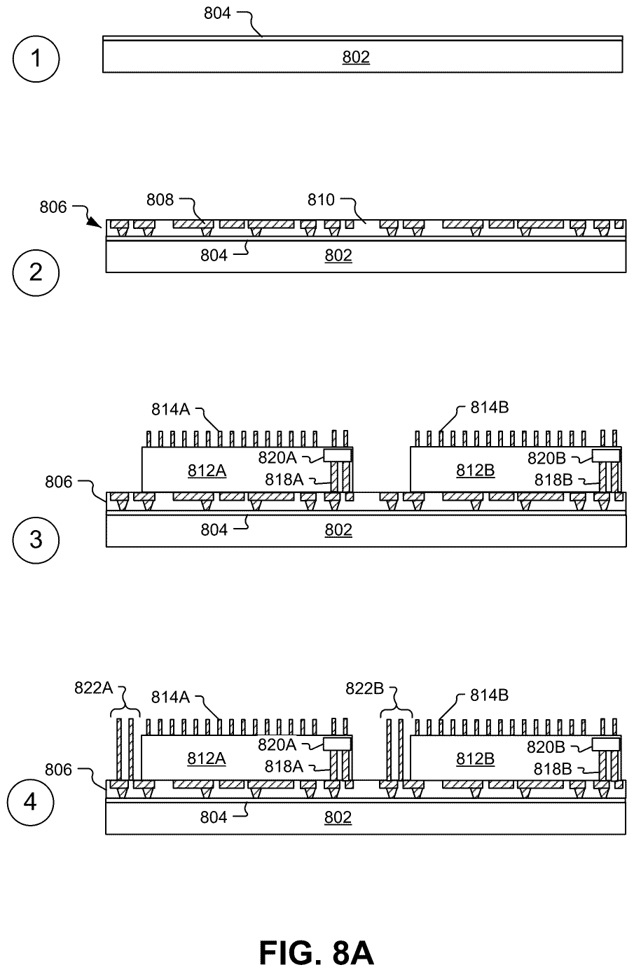

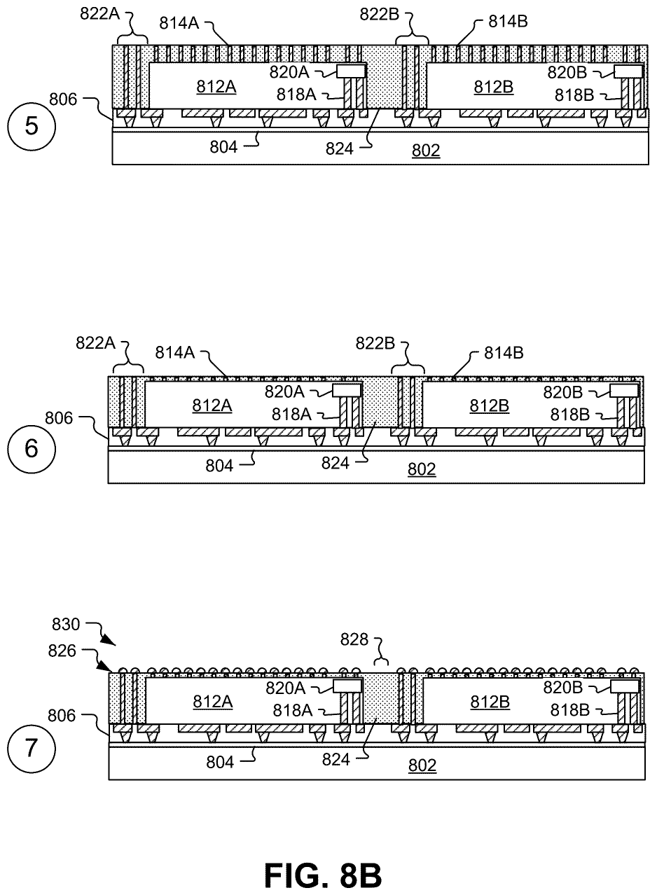

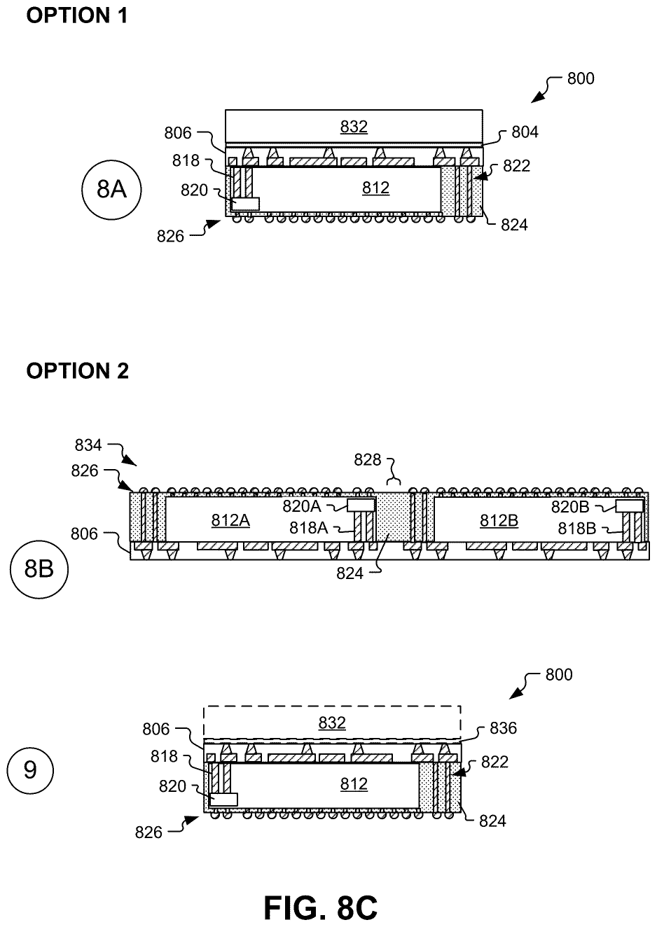

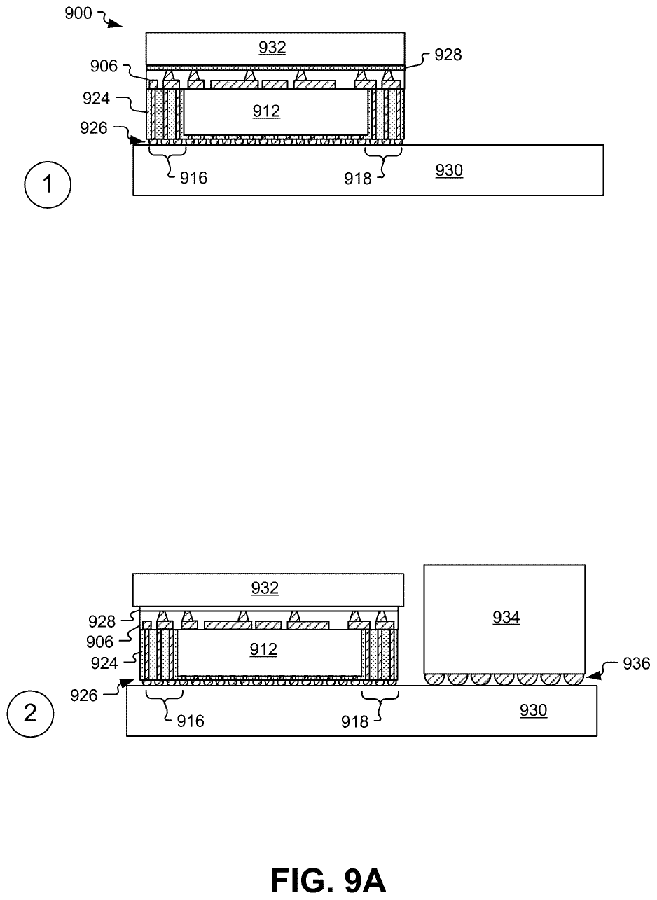

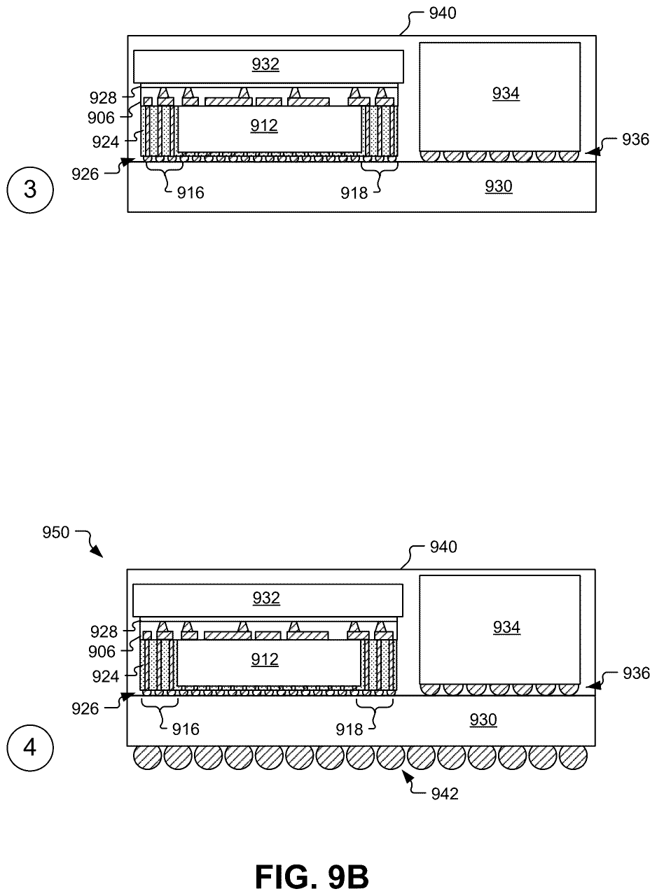

In some implementations, fabricating an integrated device package that includes two or more dies in a side-by-side arrangement where at least some of the conductive paths between dies are routed through redistribution layers over one of the dies (such as any of the integrated device packages 100, 200, 300, 400, or 500 of FIGS. 1A-5) includes multiple operations. FIGS. 6A, 6B, and 6C, together, illustrate various stages of a first exemplary sequence for providing or fabricating a device that includes a die and additional structures (e.g., interconnect conductors external to the die and redistribution layers forming pairs of connections between interconnect conductors on different sides of the die) that can be used as a component during fabrication of an integrated device package (e.g., the integrated device package 100 or 200 of FIGS. 1A and 2). FIGS. 7A, 7B, and 7C, together, illustrate various stages of a second exemplary sequence for providing or fabricating a device that includes a die and additional structures (e.g., interconnect conductors external to the die and redistribution layers forming pairs of connections between interconnect conductors on different sides of the die) that can be used as a component during fabrication of an integrated device package (e.g., the integrated device package 100 or 300 of FIGS. 1A and 3). FIGS. 8A, 8B, and 8C, together, illustrate various stages of a third exemplary sequence for providing or fabricating a device that includes a die that includes conductors coupled to additional structures (e.g., redistribution layers forming pairs of connections between interconnect conductors on different sides of the die) that can be used as a component during fabrication of an integrated device package (e.g., the integrated device package 100 or 400 of FIGS. 1A and 4). FIGS. 9A and 9C, together, illustrate various stages of an exemplary sequence for providing or fabricating an integrated device package using a device formed according to any of the sequences of FIGS. 6A-6C, 7A-7C, or 8A-8C.

It should be noted that each of the sequences of FIGS. 6A-6C, 7A-7C, 8A-8C, and 9A-9B may combine one or more stages in order to simplify and/or clarify the sequence for providing or fabricating a device or an integrated device package. In some implementations, the order of the operations described can be changed or modified. In some implementations, one or more of the operations described can be replaced or substituted without departing from the scope of the disclosure. In the following description, reference is made to various illustrative Stages of each sequence, which are numbered (using circled numbers) in each sequence. The various Stages of each of the sequences of fabrication can be performed at an individual level, a strip level, a panel level, or a wafer level.

Stage 1 of FIG. 6A illustrates a state after a carrier 602 is obtained. Optionally, a release layer 604 can be applied to the carrier 602. For example, as described with reference to Option 1 of FIG. 6C, in some embodiments, the carrier 602 is used to form a portion of a heat spreader 632 of a device 600, in which case, the release layer 604 can be omitted. In other embodiments, as described with reference to Option 2 of FIG. 6C, the carrier 602 is not used to form a portion of a heat spreader 632 of the device 600, in which case, the release layer 604 can be applied at Stage 1. When the release layer 604 is used, the release layer 604 can be applied using a spin coating technique, a spraying technique, a lamination technique, or one or more other coating techniques.

Stage 2 illustrates a state after redistribution layers 606 are formed on the carrier 602 (or on the release layer 604 if present). The redistribution layers 606 include a set of metal layers 608 that are patterned to form conductive features (e.g., lines and vias) that are separated from one another by dielectric layers 610. In the particular example illustrated in FIG. 6A, the redistribution layers 606 include multiple sets of conductive features, each corresponding to an instance of the redistribution layers 116 of FIG. 1A, arranged side-by-side on the carrier 602.

The redistribution layers 606 can be formed, for example, using a sequence of operations that form dielectric layers (e.g., individual ones of the dielectric layers 610) and patterned metal layers (e.g., individual ones of the metal layers 608). For example, each of the dielectric layers 610 can be formed using operations such as deposition or thin film application of a dielectric material. In some cases, the dielectric material can be patterned using photolithography techniques (e.g., exposure and development). Each of the metal layers 608 can be formed using operations such as deposition or thin film application. For example, a patterning layer can be formed (e.g. using photolithography techniques), and metal can be deposited on the patterning layer to form a patterned metal layer. As another example, a metal foil can be applied and patterned using subtractive techniques, such as etching guided by a patterned layer. Underbump metallization layers can be formed on portions of a top metal layer (in the orientation illustrated in FIG. 6A) that correspond to contacts of the redistribution layers 606. The contacts of the redistribution layers 606 can be interconnected by conductors of the metal layers 608 in pairwise arrangements to form conductive paths therebetween.

Stage 3 illustrates a state after one or more dies 612 (e.g., a die 612A and a die 612B) are coupled to the redistribution layers 606, and conductive posts 614 (e.g., conductive posts 614A on the die 612A and conductive posts 614B on the die 612B) are electrically coupled to the dies 612. The conductive posts 614A are electrically coupled to contacts of a face of the die 612A, and the conductive posts 614B are electrically coupled to contacts of a face of the die 612B. In some embodiments, a back, opposite the face, of each of the dies 612 is coupled to the redistribution layers 606 using adhesive. In some such embodiments, the backs of the dies 612 may be devoid of contacts.

The conductive posts 614 can be formed on or coupled to the dies 612 before the dies 612 are coupled to the redistribution layers 606. In other cases, the conductive posts 614 are formed on or coupled to the dies 612 after the dies 612 are coupled to the redistribution layers 606. For example, one or more metal deposition processes can be used to form the conductive posts 614 on the dies 612 while the dies 612 are disposed on the carrier 602. As another example, the conductive posts 614 can be formed separately and subsequently attached to contacts of the dies 612.

Stage 4 illustrates a state after first conductive pillars 616 and second conductive pillars 618 are electrically coupled to contacts of the redistribution layers 606. In the example illustrated in FIG. 6A, a set of first conductive pillars 616A are formed along a first edge of the die 612A, a set of second conductive pillars 618A are formed along a second edge of the die 612A, a set of first conductive pillars 616B are formed along a first edge of the die 612B, and a set of second conductive pillars 618B are formed along a second edge of the die 612B. For example, one or more metal deposition processes (e.g., plating) can be used to form the conductive pillars 616, 618. As another example, the conductive pillars 616, 618 can be formed separately and subsequently attached to the contacts of the redistribution layers 606.

Stage 5 of FIG. 6B illustrates a state after mold compound 620 is applied to at least partially encapsulate the dies 612, the conductive posts 614, and the conductive pillars 616, 618. Stage 6 illustrates a state after grinding operations are performed to expose ends of the conductive posts 614 and the conductive pillars 616, 618. The grinding operations also planarize the top surface (in the orientation illustrated in FIG. 6B).

Stage 7 illustrates a stage after formation of bumps 624 on exposed ends of the conductive posts 614 and the conductive pillars 616, 618 to form an assembly 630. For example, the bumps 624 can be formed using various deposition techniques, such as plating or printing.

FIG. 6C illustrates two Options including Option 1 and Option 2. Option 1 illustrates aspects of a sequence for fabrication in which a portion of the carrier 602 is used to form a heat spreader 632. For example, Stage 8A illustrates a stage after the assembly 630 of FIG. 6B is cut to form a device 600. To illustrate, the assembly 630 (including the carrier 602) can be cut along various streets 626 to separate a device that includes the die 612A from a device that includes the die 612B (either of which can correspond to the device 600 of Stage 8A of FIG. 6C).

Option 2 illustrates aspects of a sequence for fabrication in which the carrier 602 is not used to form the heat spreader. For example, Stage 8B illustrates a stage after the carrier 602 has been removed from the assembly 630 of FIG. 6B to form an assembly 634. Continuing this example, Stage 9 illustrates a state after the assembly 634 is cut to form a device 600. To illustrate, the assembly 634 can be cut along various streets 626 to separate a device that includes the die 612A from a device that includes the die 612B (either of which can correspond to the device 600 of Stage 9 of FIG. 6C). Optionally, a dielectric layer 628 (e.g., an adhesive layer) can be coupled to the redistribution layers 606 of the device 600, and a heat spreader 632 can be coupled to the dielectric layer 628.

Formation of the device 600 is complete after Stage 8A of Option 1 or after Stage 9 of Option 2 of FIG. 6C. For example, the device 600 includes a die (e.g., one of the dies 612) that includes a plurality of contacts (e.g., contacts electrically coupled to the conductive posts 614) on a first side (e.g., the bottom in the orientations illustrated at Stages 8A and 9). The device 600 also includes first interconnect conductors (e.g., the conductive pillars 616) along a first edge (e.g., the left side in the orientations illustrated at Stages 8A and 9) of the die 612, and second interconnect conductors (e.g., the conductive pillars 618) external to the die 612 and along a second edge (e.g., the right side in the orientations illustrated at Stages 8A and 9) of the die 612. In this example, the device 600 also includes redistribution layers (e.g., the redistribution layers 606) coupled to a second side (e.g., the top in the orientations illustrated at Stages 8A and 9) of the die 612, where the redistribution layers define a plurality of pairs of conductive paths between the first interconnect conductors and the second interconnect conductors, as described with reference to FIG. 1A.

Stage 1 of FIG. 7A illustrates a state after a carrier 702 is obtained. Optionally, a release layer 704 can be applied to the carrier 702. For example, as described with reference to Option 1 of FIG. 7C, in some embodiments, the carrier 702 is used to form a portion of a heat spreader 732 of device 700, in which case, the release layer 704 can be omitted. In other embodiments, as described with reference to Option 2 of FIG. 7C, the carrier 702 is not used to form a portion of a heat spreader 732 of the device 700, in which case, the release layer 704 can be applied at Stage 1. When the release layer 704 is used, the release layer 704 can be applied using a spin coating technique, a spraying technique, a lamination technique, or one or more other coating techniques.

Stage 2 illustrates a state after redistribution layers 706 are formed on the carrier 702 (or on the release layer 704 if present). The redistribution layers 706 include a set of metal layers 708 that are patterned to form conductive features (e.g., lines and vias) that are separated from one another by dielectric layers 710. In the particular example illustrated in FIG. 7A, the redistribution layers 706 include multiple sets of conductive features, each corresponding to an instance of the redistribution layers 116 of FIG. 1A, arranged side-by-side on the carrier 702. The redistribution layers 706 can be formed using one or more of the techniques described with reference to FIG. 6A regarding formation of the redistribution layers 606. Contacts of the redistribution layers 706 can be interconnected by conductors of the metal layers 708 in pairwise arrangements to form conductive paths therebetween.

Stage 3 illustrates a state after one or more dies 712 and components 716 are coupled to the redistribution layers 706. For example, in FIG. 7A, the dies 712 include a die 712A and a die 712B, and the components 716 include a component 716A and a component 716B. At Stage 3, conductive posts 714 are electrically coupled to the dies 712, and conductive posts 720 are electrically coupled to the components 716. To illustrate, conductive posts 714A are electrically coupled to contacts of a face of the die 712A, conductive posts 714B are electrically coupled to contacts of a face of the die 712B, conductive posts 720A are electrically coupled to contacts of a face of the component 716A, and conductive posts 720B are electrically coupled to contacts of a face of the component 716B. In some embodiments, a back, opposite the face, of each of the dies 712 is coupled to the redistribution layers 706 using adhesive. In some such embodiments, the backs of the dies 712 may be devoid of contacts. A back of each of the components 716 is electrically coupled to the redistribution layers 706, and conductors 718 of the components are through conductors. To illustrate, conductors 718A of the component 716A electrically couple respective ones of the conductive posts 720A to corresponding contacts of the redistribution layers 706, and conductors 718B of the component 716B electrically couple respective ones of the conductive posts 720B to corresponding contacts of the redistribution layers 706.

The conductive posts 714 can be formed on or coupled to the dies 712 before the dies 712 are coupled to the redistribution layers 706. In other cases, the conductive posts 714 are formed on or coupled to the dies 712 after the dies 712 are coupled to the redistribution layers 706. For example, one or more metal deposition processes can be used to form the conductive posts 714 on the dies 712 while the dies 712 are disposed on the carrier 702. As another example, the conductive posts 714 can be formed separately and subsequently attached to contacts of the dies 712. Likewise, the conductive posts 720 can be formed on or coupled to the components 716 before the components 716 are coupled to the redistribution layers 706 or after the components 716 are coupled to the redistribution layers 706.

Stage 4 illustrates a state after first conductive pillars 722 are electrically coupled to contacts of the redistribution layers 706. In the example illustrated in FIG. 7A, a set of conductive pillars 722A are formed along an edge of the die 712A, and a set of conductive pillars 722B are formed along an edge of the die 712B. For example, one or more metal deposition processes (e.g., plating) can be used to form the conductive pillars 722. As another example, the conductive pillars 722 can be formed separately and subsequently attached to the contacts of the redistribution layers 706.

Stage 5 of FIG. 7B illustrates a state after mold compound 724 is applied to at least partially encapsulate the dies 712, the conductive pillars 722 the conductive posts 714, the conductive pillars 722, and the components 716. Stage 6 illustrates a state after grinding operations are performed to expose ends of the conductive posts 714, the conductive posts 720, and the conductive pillars 722. The grinding operations also planarize the top surface (in the orientation illustrated in FIG. 7B).

Stage 7 illustrates a stage after formation of bumps 726 on exposed ends of the conductive posts 714, the conductive posts 720, and the conductive pillars 722 to form an assembly 730. For example, the bumps 726 can be formed using various deposition techniques, such as plating or printing.

FIG. 7C illustrates two Options including Option 1 and Option 2. Option 1 illustrates aspects of a sequence for fabrication in which a portion of the carrier 702 is used to form a heat spreader 732. For example, Stage 8A illustrates a stage after the assembly 730 of FIG. 7B is cut to form a device 700. To illustrate, the assembly 730 (including the carrier 702) can be cut along various streets 728 to separate a device that includes the die 712A from a device that includes the die 712B (either of which can correspond to the device 700 of Stage 8A of FIG. 7C).

Option 2 illustrates aspects of a sequence for fabrication in which the carrier 702 is not used to form the heat spreader. For example, Stage 8B illustrates a stage after the carrier 702 has been removed from the assembly 730 of FIG. 7B to form an assembly 734. Continuing this example, Stage 9 illustrates a state after the assembly 734 is cut to form a device 700. To illustrate, the assembly 734 can be cut along various streets 728 to separate a device that includes the die 712A from a device that includes the die 712B (either of which can correspond to the device 700 of Stage 9 of FIG. 7C). Optionally, a dielectric layer 736 (e.g., an adhesive layer) can be coupled to the redistribution layers 706 of the device 700, and a heat spreader 732 can be coupled to the dielectric layer 736.

Formation of the device 700 is complete after Stage 8A of Option 1 or after Stage 9 of Option 2 of FIG. 7C. For example, the device 700 includes a die (e.g., one of the dies 712) that includes a plurality of contacts (e.g., contacts electrically coupled to the conductive posts 714) on a first side (e.g., the bottom in the orientations illustrated at Stages 8A and 9). The device 700 also includes first interconnect conductors (e.g., the conductors 718 of the component 716) along a first edge (e.g., the left side in the orientations illustrated at Stages 8A and 9) of the die 712, and second interconnect conductors (e.g., the conductive pillars 722) external to the die 712 and along a second edge (e.g., the right side in the orientations illustrated at Stages 8A and 9) of the die 712. In this example, the device 700 also includes redistribution layers (e.g., the redistribution layers 706) coupled to a second side (e.g., the top in the orientations illustrated at Stages 8A and 9) of the die 712, where the redistribution layers define a plurality of pairs of conductive paths between the first interconnect conductors and the second interconnect conductors, as described with reference to FIG. 1A.

Stage 1 of FIG. 8A illustrates a state after a carrier 802 is obtained. Optionally, a release layer 804 can be applied to the carrier 802. For example, as described with reference to Option 1 of FIG. 8C, in some embodiments, the carrier 802 is used to form a portion of a heat spreader 832 of device 800, in which case, the release layer 804 can be omitted. In other embodiments, as described with reference to Option 2 of FIG. 8C, the carrier 802 is not used to form a portion of a heat spreader 832 of the device 800, in which case, the release layer 804 can be applied at Stage 1. When the release layer 804 is used, the release layer 804 can be applied using a spin coating technique, a spraying technique, a lamination technique, or one or more other coating techniques.

Stage 2 illustrates a state after redistribution layers 806 are formed on the carrier 802 (or on the release layer 804 if present). The redistribution layers 806 include a set of metal layers 808 that are patterned to form conductive features (e.g., lines and vias) that are separated from one another by dielectric layers 810. In the particular example illustrated in FIG. 8A, the redistribution layers 806 include multiple sets of conductive features, each corresponding to an instance of the redistribution layers 116 of FIG. 1A, arranged side-by-side on the carrier 802. The redistribution layers 806 can be formed using one or more of the techniques described with reference to FIG. 6A regarding formation of the redistribution layers 606. Contacts of the redistribution layers 806 can be interconnected by conductors of the metal layers 808 in pairwise arrangements to form conductive paths therebetween.

Stage 3 illustrates a state after one or more dies 812 that include internal conductors 818 are coupled to the redistribution layers 806. For example, in FIG. 8A, the dies 812 include a die 812A with conductors 818A and a die 812B with conductors 818B. Circuitry 820 is formed in or on a face of each of the dies 812, and the conductors 818 are electrically coupled, at a first end, to the circuitry 820. For example, the conductors 818A within the die 812A are electrically coupled, at a first end, to circuitry 820A, and the conductors 818B are electrically coupled, at a first end, to circuitry 820B within the die 812B. Second ends of the conductors 818 are coupled to or form contacts on a back (e.g., a bottom surface in the orientation illustrated in FIG. 8A) of each die 812. The contacts on the back of each of the dies 812 are electrically coupled to the redistribution layers 806.

At Stage 3, conductive posts 814 are electrically coupled to the dies 812. To illustrate, conductive posts 814A are electrically coupled to contacts of the face of the die 812A, and conductive posts 814B are electrically coupled to contacts of the face of the die 812B. The conductive posts 814 can be formed on or coupled to the dies 812 before the dies 812 are coupled to the redistribution layers 806. In other cases, the conductive posts 814 are formed on or coupled to the dies 812 after the dies 812 are coupled to the redistribution layers 806. For example, one or more metal deposition processes can be used to form the conductive posts 814 on the dies 812 while the dies 812 are disposed on the carrier 802. As another example, the conductive posts 814 can be formed separately and subsequently attached to contacts of the dies 812.

Stage 4 illustrates a state after conductive pillars 822 are electrically coupled to contacts of the redistribution layers 806. In the example illustrated in FIG. 8A, a set of conductive pillars 822A are formed along an edge of the die 812A, and a set of conductive pillars 822B are formed along an edge of the die 812B. For example, one or more metal deposition processes (e.g., plating) can be used to form the conductive pillars 822. As another example, the conductive pillars 822 can be formed separately and subsequently attached to the contacts of the redistribution layers 806.

Stage 5 of FIG. 8B illustrates a state after mold compound 824 is applied to at least partially encapsulate the dies 812, the conductive pillars 822, and the conductive posts 814. Stage 6 illustrates a state after grinding operations are performed to expose ends of the conductive posts 814 and the conductive pillars 822. The grinding operations also planarize the top surface (in the orientation illustrated in FIG. 8B).

Stage 7 illustrates a stage after formation of bumps 826 on exposed ends of the conductive posts 814 and the conductive pillars 822 to form an assembly 830. For example, the bumps 826 can be formed using various deposition techniques, such as plating or printing.

FIG. 8C illustrates two Options including Option 1 and Option 2. Option 1 illustrates aspects of a sequence for fabrication in which a portion of the carrier 802 is used to form a heat spreader 832. For example, Stage 8A illustrates a stage after the assembly 830 of FIG. 8B is cut to form a device 800. To illustrate, the assembly 830 (including the carrier 802) can be cut along various streets 828 to separate a device that includes the die 812A from a device that includes the die 812B (either of which can correspond to the device 800 of Stage 8A of FIG. 8C).

Option 2 illustrates aspects of a sequence for fabrication in which the carrier 802 is not used to form the heat spreader. For example, Stage 8B illustrates a stage after the carrier 802 has been removed from the assembly 830 of FIG. 8B to form an assembly 834. Continuing this example, Stage 9 illustrates a state after the assembly 834 is cut to form a device 800. To illustrate, the assembly 834 can be cut along various streets 828 to separate a device that includes the die 812A from a device that includes the die 812B (either of which can correspond to the device 800 of Stage 9 of FIG. 8C). Optionally, a dielectric layer 836 (e.g., an adhesive layer) can be coupled to the redistribution layers 806 of the device 800, and a heat spreader 832 can be coupled to the dielectric layer 836.

Formation of the device 800 is complete after Stage 8A of Option 1 or after Stage 9 of Option 2 of FIG. 8C. For example, the device 800 includes a die (e.g., one of the dies 812) that includes a plurality of contacts (e.g., contacts electrically coupled to the conductive posts 814) on a first side (e.g., the bottom in the orientations illustrated at Stages 8A and 9). The device 800 also includes first interconnect conductors (e.g., the conductors 818 of the component 816) along a first edge (e.g., the left side in the orientations illustrated at Stages 8A and 9) of the die 812, and second interconnect conductors (e.g., the conductive pillars 822) external to the die 812 and along a second edge (e.g., the right side in the orientations illustrated at Stages 8A and 9) of the die 812. In this example, the device 800 also includes redistribution layers (e.g., the redistribution layers 806) coupled to a second side (e.g., the top in the orientations illustrated at Stages 8A and 9) of the die 812, where the redistribution layers define a plurality of pairs of conductive paths between the first interconnect conductors and the second interconnect conductors, as described with reference to FIG. 1A.

FIGS. 9A and 9C, together, illustrate various stages of an exemplary sequence for providing or fabricating an integrated device package using any of the devices 600, 700, 800 formed according to any of the sequences of FIGS. 6A-6C, 7A-7C, or 8A-8C. Stage 1 of FIG. 9A illustrates a stage after a device 900 is electrically coupled to contacts of a package substrate 930. For example, various flip-chip die attach operations can be used to heat bumps 926 to couple the device 900 to contacts of the package substrate 930. The device 900 can include or correspond to any of the devices 100, 200, 300, 400, 500, 600, 700, or 800 of FIGS. 1A, 2, 3, 4, 5, 6C, 7C, or 8C. For example, the device 900 includes a die 912 that includes a plurality of contacts (e.g., contacts electrically coupled to the bumps 926) on a first side (e.g., the bottom in the orientation illustrated at Stage 1). The device 900 also includes first interconnect conductors 916 along a first edge (e.g., the left side in the orientation illustrated at Stage 1) of the die 912, and second interconnect conductors 918 external to the die 912 and along a second edge (e.g., the right side in the orientation illustrated at Stage 1) of the die 912. Although the first interconnect conductors 916 are illustrated in FIGS. 9A and 9B as external to the die 912 and within mold compound 924 (e.g., similar to the device 600 of FIG. 6C), in other embodiments, the first interconnect conductors 916 include through vias within another component (e.g., similar to the device 700 of FIG. 7C) or conductors within the die 912 (e.g., similar to the device 800 of FIG. 8C).

The device 900 also includes redistribution layers 906 coupled to a second side (e.g., the top in the orientations illustrated at Stage 1) of the die 912, where the redistribution layers 906 define a plurality of pairs of conductive paths between the first interconnect conductors 916 and the second interconnect conductors 918. Further, in the example illustrated, the device 900 includes an optional heat spreader 932 coupled to the redistribution layers 906 by a dielectric layer 928. In other examples, the heat spreader 932 and the dielectric layer 928 are omitted. The heat spreader 932 can include bulk silicon, a metal block, or another high-thermal conductivity material.

Stage 2 illustrates a stage after another die 934 is electrically coupled to contacts of the package substrate 930 using solder 936 (e.g., solder balls, solder bumps, or solder caps of conductive posts). For example, various flip-chip die attach operations can be used to heat the solder 936 to couple the die 934 to contacts of the package substrate 930.

Stage 3 of FIG. 9B illustrates a state after mold compound 940 is applied to at least partially encapsulate the die 912 and the die 934. The mold compound 940 may also at least partially encapsulate the heat spreader 932. The mold compound 940 is optional and is omitted in some implementations, in which case the operations described with reference to Stage 3 are omitted.

Stage 4 illustrates a state after solder balls 942 are electrically coupled to off-package contacts of the package substrate 930. In some implementations, the operations described with reference to any one or more of Stages 1-4 of FIGS. 9A and 9B can be performed at a strip level or a panel level. For example, the package substrate 930 illustrated in Stages 1-4 can correspond to a portion of a strip of package substrates or a panel of package substrates. In such implementations, Stage 4 illustrates a state after package singulation, such as by cutting the strip or panel of package substrates to form an individual integrated device package 950.

Formation of the integrated device package 950 is complete after Stage 4 of FIG. 9B. In the example illustrated, the integrated device package 950 includes the die 912, which is an example of the die 102 of any of FIGS. 1A, 2, 3, 4, or 5. The integrated device package 950 also includes the die 934, which is an example of the die 132 of any of FIGS. 1A, 2, 3, 4, or 5. The integrated device package 950 also includes the interconnect conductors 916, 918, which are, respectively, examples of the first interconnect conductors 108 and the second interconnect conductors 114 of any of FIGS. 1A, 2, 3, 4, or 5. The integrated device package 950 also includes the redistribution layers 906, which are examples of the redistribution layers 116 of any of FIGS. 1A, 2, 3, 4, or 5. Optionally, the integrated device package 950 also includes the heat spreader 932 and the dielectric layer 928, which are examples, respectively, of the heat spreader 122 and the dielectric layer 126 of any of FIGS. 1A, 2, 3, 4, or 5.

In some implementations, the operations described with reference to certain of the Stages of FIGS. 9A and 9B can be changed. For example, during formation of the integrated device package 500 of FIG. 5, the die 934 is electrically coupled to the package substrate 930 before the heat spreader 932 is attached to the die 912 (via the redistribution layers 906) and the die 934.

### Exemplary Flow Diagram of a Method for Fabricating an Integrated Device Package

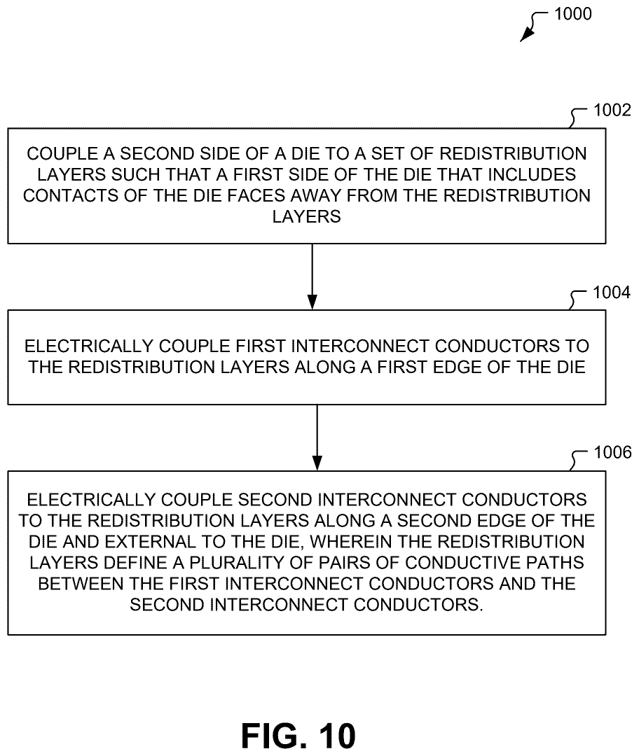

In some implementations, fabricating a device as a component of an integrated device package includes several processes. FIG. 10 illustrates an exemplary flow diagram of a method 1000 for providing or fabricating such a device. In some implementations, the method 1000 of FIG. 10 may be used to provide or fabricate the device 600 of FIG. 6C, the device 700 of FIG. 7C, the device 800 of FIG. 8C, or any of the devices 100, 200, 300, 400, 500 of FIGS. 1A, 2, 3, 4, or 5 or the integrated device package 950 of FIG. 9B.

It should be noted that the method 1000 of FIG. 10 may combine one or more processes in order to simplify and/or clarify the method for providing or fabricating an integrated device. In some implementations, the order of the processes may be changed or modified.

The method 1000 includes, at block 1002, coupling (e.g., using an adhesive layer) a second side of a die to a set of redistribution layers such that a first side of the die that includes contacts of the die faces away from the redistribution layers. For example, the die can include or correspond to the die 102 of FIG. 1A. In this example, the second side of the die corresponds to the side 118 (e.g., the back) of the die 102, which is opposite the side 106 (e.g., the face) of the die 102. In this example, the face of the die 102 includes contacts coupled to the contacts 104 of the package substrate 130. In some implementations, Stage 3 of FIG. 6A, Stage 3 of FIG. 7A, and Stage 3 of FIG. 8A illustrate and describe examples of coupling a second side of a die to a set of redistribution layers such that a first side of the die that includes contacts of the die faces away from the redistribution layers.

The method 1000 includes, at block 1004, electrically coupling first interconnect conductors to the redistribution layers along a first edge of the die. The first interconnect conductors can be internal to the die or external to the die. As an example, Stage 4 of FIG. 6A illustrates and describes operations to electrically couple the first conductive pillars 618A to the redistribution layers 606 along edges of the die 612A. As another example, Stage 3 of FIG. 7A illustrates and describes operations to electrically couple a component 716A that includes conductors 718A to the redistribution layers 706 along a first edge of the die 712A. As yet another example, Stage 3 of FIG. 8A illustrates and describes operations to electrically couple conductors 818 within a die 812 along a first edge of the die 812 to the redistribution layers 806.

The method 1000 includes, at block 1006, electrically coupling second interconnect conductors to the redistribution layers along a second edge of the die and external to the die, where the redistribution layers define a plurality of pairs of conductive paths between the first interconnect conductors and the second interconnect conductors. As an example, Stage 4 of FIG. 6A illustrates and describes operations to electrically couple the second conductive pillars 618A to the redistribution layers 606 along a second edge of the die 612A. As another example, Stage 4 of FIG. 7A illustrates and describes operations to electrically couple the second conductive pillars 722A to the redistribution layers 706 along a second edge of the die 712A. As another example, Stage 4 of FIG. 8A illustrates and describes operations to electrically couple the conductive pillars 822A to the redistribution layers 806 along a second edge of the die 812A. In each example, the redistribution layers form pairs of conductive paths between the first and second interconnect conductors. The first edge of the die can be adjacent to the second edge of the die or opposite the second edge of the die.

In some implementations, the redistribution layers are formed on a carrier that is subsequently removed. For example, in such implementations, the method 1000 can include forming the redistribution layers on a carrier substrate (e.g., the carrier 602 of FIGS. 6A-6C, the carrier 702 of FIGS. 7A-7C, or the carrier 802 of FIGS. 8A-8C) and separating the redistribution layers and the die from the carrier substrate after the first and second interconnect conductors are coupled to the redistribution layers. To illustrate, the operations described with reference to Option 2 of each of FIGS. 6C, 7C and 8C include separating the carrier from the redistribution layers after the first conductive pillars and the second conductive pillars are coupled to the redistribution layers.

In some implementations, the redistribution layers are formed on a wafer that is cut during fabrication of a device such that a portion of the wafer remains with the device to act as a heat spreader. To illustrate, the operations described with reference to Option 1 of each of FIGS. 6C, 7C and 8C describe cutting the carrier to form a heat spreader. In such implementations, the method 1000 can include forming the redistribution layers on a carrier and, after the first interconnect conductors and the second interconnect conductors are coupled to the redistribution layers, cutting the carrier to form a heat spreader coupled to the redistribution layers.

In some examples, the method 1000 is complete at block 1006. For example, the operations described with reference to blocks 1002-1006 of the method 1000 (optionally in combination with one or more additional operations) can be performed to fabricate any of the devices 100, 200, 300, 400, 500, 600, 700 or 800 of FIGS. 1A, 2-5, 6C, 7C, or 8C. In other examples, a device fabricated using the operations described with reference to blocks 1002-1006 of the method 1000 can be used as a component of an integrated device package. In such examples, the method 1000 can further include additional operations to couple the device and one or more additional dies to a package substrate.

To illustrate, the method 1000 can further include electrically coupling the contacts of the die, the first interconnect conductors, and the second interconnect conductors to corresponding contacts of a package substrate. For example, Stage 1 of FIG. 9A illustrates and describes operations to couple the device 900 to the package substrate 930. In this example, coupling the device 900 to the package substrate 930 includes electrically coupling the contacts of the die 912, the first interconnect conductors 916, and the second interconnect conductors 918 to corresponding contacts of a package substrate 930.

The method 1000 can also include electrically coupling a second die to the package substrate such that: a first communication channel between the die and the second die includes the first interconnect conductors, conductors of the redistribution layers, the second interconnect conductors, and first conductors of the package substrate; and a second communication channel between the die and the second die includes second conductors of the package substrate. Stage 2 of FIG. 9A illustrates and describes examples of operations to couple the die 934 to the package substrate 930.

In some implementations, the method 1000 includes coupling a heat spreader to a side of the redistribution layers opposite the die. The heat spreader can be coupled to the redistribution layers using an adhesive layer. In some implementations, a footprint of the heat spreader is larger than a footprint of one or more of the dies of an integrated device package. The heat spreader includes or corresponds to a bulk silicon block or a metal block.

### Exemplary Electronic Devices

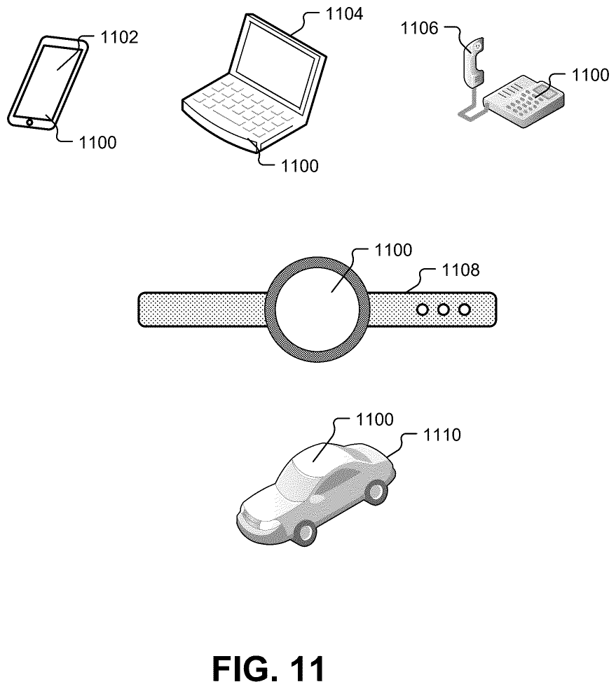

FIG. 11 illustrates various electronic devices that may include or be integrated with any of the integrated device packages 100, 200, 300, 400, 500, or 950 of FIGS. 1A, 2-5, or 9B or the devices 600, 700, or 800 of FIGS. 6C, 7C, or 8C. For example, a mobile phone device 1102, a laptop computer device 1104, a fixed location terminal device 1106, a wearable device 1108, or a vehicle 1110 (e.g., an automobile or an aerial device) may include a device 1100. The device 1100 can include, for example, any of the devices 600, 700, or 800 and/or any of the integrated device packages 100, 200, 300, 400, 500, or 950 described herein. The devices 1102, 1104, 1106, and 1108 and the vehicle 1110 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-11 may be rearranged and/or combined into a single component, process, feature or function or embodied in several components, processes, or functions. Additional elements, components, processes, and/or functions may also be added without departing from the disclosure. It should also be noted FIGS. 1A-11 and its corresponding description in the present disclosure is not limited to dies and/or ICs. In some implementations, FIGS. 1A-11 and its corresponding description may be used to manufacture, create, provide, and/or produce devices and/or integrated devices. In some implementations, a device may include a die, an integrated device, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a die that includes a plurality of contacts on a first side; first interconnect conductors along a first edge of the die; second interconnect conductors external to the die and along a second edge of the die; and redistribution layers coupled to a second side of the die, where the redistribution layers define a plurality of pairs of conductive paths between the first interconnect conductors and the second interconnect conductors.

Example 2 includes the device of Example 1, where the first interconnect conductors, the second interconnect conductors, or both, include through mold vias.

Example 3 includes the device of Example 1 or Example 2, where the first interconnect conductors include through vias within the die.

Example 4 includes the device of Example 1 or Example 2, and further includes an interconnect component coupled to the redistribution layers adjacent to the first edge of the die, wherein the interconnect component includes the first interconnect conductors.

Example 5 includes the device of Example 1, 2, or 4, where the second side of the die corresponds to a back of the die and is devoid of contacts.

Example 6 includes the device of any of Examples 1 to 5 and further includes a heat spreader coupled to a side of the redistribution layers opposite the die.

Example 7 includes the device of Example 6 and further includes a dielectric layer between the redistribution layers and the heat spreader.

Example 8 includes the device of Example 6 or Example 7, where the heat spreader comprises a bulk silicon block.

Example 9 includes the device of Example 6 or Example 6, where the heat spreader comprises a metal block.

According to Example 10, a side-by-side integrated device package includes a package substrate; a first die electrically coupled, on a first side of the first die, to a first set of contacts of the package substrate; a second die electrically coupled to a second set of contacts of the package substrate; a mold compound that at least partially encapsulates the first die; first interconnect conductors along a first edge of the first die; second interconnect conductors external to the first die and along a second edge of the first die; and redistribution layers coupled to a second side of the first die, and where the redistribution layers define a plurality of pairs of conductive paths between the first interconnect conductors and the second interconnect conductors.

Example 11 includes the side-by-side integrated device package of Example 10, where the first interconnect conductors, the second interconnect conductors, or both, include through mold vias.

Example 12 includes the side-by-side integrated device package of Example 10 or Example 11, where the first interconnect conductors include through vias within the first die.

Example 13 includes the side-by-side integrated device package of Example 10 or Example 11 and further includes an interconnect component coupled to the redistribution layers adjacent to the first edge of the first die, wherein the interconnect component includes the first interconnect conductors.

Example 14 includes the side-by-side integrated device package of any of Examples 10 to 13, where the first edge and the second edge are opposite edges of the first die.

Example 15 includes the side-by-side integrated device package of any of Examples 10, 11, 13, or 14, where the second side of the first die corresponds to a back of the first die and is devoid of contacts.

Example 16 includes the side-by-side integrated device package of any of Examples 10 to 15 and further includes a heat spreader coupled to a side of the redistribution layers opposite the first die.

Example 17 includes the side-by-side integrated device package of Example 16, where a footprint of the heat spreader is larger than a footprint of the first die.

Example 18 includes the side-by-side integrated device package of Example 16 or Example 17 and further includes a dielectric layer between the redistribution layers and the heat spreader.

Example 19 includes the side-by-side integrated device package of any of Examples 16 to 18, where the heat spreader comprises a bulk silicon block.

Example 20 includes the side-by-side integrated device package of any of Examples 16 to 18, where the heat spreader comprises a metal block.

According to Example 21, a method includes coupling a second side of a die to a set of redistribution layers such that a first side of the die that includes contacts of the die faces away from the redistribution layers; electrically coupling first interconnect conductors to the redistribution layers along a first edge of the die and external to the die; and electrically coupling second interconnect conductors to the redistribution layers along a second edge of the die and external to the die, where the redistribution layers define a plurality of pairs of conductive paths between the first interconnect conductors and the second interconnect conductors.

Example 22 includes the method of Example 21 and further includes forming the redistribution layers on a carrier substrate; and separating the redistribution layers and the die from the carrier substrate after the first interconnect conductors and the second interconnect conductors are coupled to the redistribution layers.

Example 23 includes the method of Example 21 and further includes forming the redistribution layers on a carrier substrate; and after the first interconnect conductors and the second interconnect conductors are coupled to the redistribution layers, cutting the carrier substrate to form a heat spreader coupled to the redistribution layers.

Example 24 includes the method of any of Examples 21 to 23 and further includes electrically coupling the contacts of the die, the first interconnect conductors, and the second interconnect conductors to corresponding contacts of a package substrate.

Example 25 includes the method of Example 24 and further includes electrically coupling a second die to the package substrate such that: a first communication channel between the die and the second die includes the first interconnect conductors, conductors of the redistribution layers, the second interconnect conductors, and first conductors of the package substrate; and a second communication channel between the die and the second die includes second conductors of the package substrate.

Example 26 includes the method of any of Examples 21 to 25, where the first edge and the second edge are opposite edges of the die.

Example 27 includes the method of any of Examples 21 to 26, where the second side of the die corresponds to a back of the die that does not include electrical contacts.

Example 28 includes the method of any of Examples 21 to 27 and further includes coupling a heat spreader to a side of the redistribution layers opposite the die.

Example 29 includes the method of Example 28, where a footprint of the heat spreader is larger than a footprint of the die.

Example 30 includes the method of Example 28 or Example 29, where the heat spreader is coupled to the redistribution layers using an adhesive layer.

Example 31 includes the method of any of Examples 28 to 30, where the heat spreader comprises a bulk silicon block.

Example 32 includes the method of any of Examples 28 to 30, where the heat spreader comprises a metal block.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a die that includes a plurality of contacts on a first side;
first interconnect conductors along a first edge of the die;
second interconnect conductors external to the die and along a second edge of the die; and
redistribution layers coupled to a second side of the die, wherein the redistribution layers define a plurality of pairs of conductive paths between the first interconnect conductors and the second interconnect conductors.

2. The device of claim 1, wherein the first interconnect conductors, the second interconnect conductors, or both, include through mold vias.

3. The device of claim 1, wherein the first interconnect conductors include through vias within the die.

4. The device of claim 1, further comprising an interconnect component coupled to the redistribution layers adjacent to the first edge of the die, wherein the interconnect component includes the first interconnect conductors.

5. The device of claim 1, further comprising a heat spreader coupled to a side of the redistribution layers opposite the die.

6. The device of claim 5, wherein the heat spreader comprises a bulk silicon block.

7. The device of claim 5, wherein the heat spreader comprises a metal block.

8. A side-by-side integrated device package comprising:
a package substrate;
a first die electrically coupled, on a first side of the first die, to a first set of contacts of the package substrate;
a second die electrically coupled to a second set of contacts of the package substrate;
a mold compound that at least partially encapsulates the first die;
first interconnect conductors along a first edge of the first die;
second interconnect conductors external to the first die and along a second edge of the first die; and
redistribution layers coupled to a second side of the first die, wherein the redistribution layers define a plurality of pairs of conductive paths between the first interconnect conductors and the second interconnect conductors.

9. The side-by-side integrated device package of claim 8, wherein the first interconnect conductors, the second interconnect conductors, or both, include through mold vias.

10. The side-by-side integrated device package of claim 8, wherein the first interconnect conductors include through vias within the first die.

11. The side-by-side integrated device package of claim 8, further comprising an interconnect component coupled to the redistribution layers adjacent to the first edge of the first die, wherein the interconnect component includes the first interconnect conductors.

12. The side-by-side integrated device package of claim 8, wherein the first edge and the second edge are opposite edges of the first die.

13. The side-by-side integrated device package of claim 8, further comprising a heat spreader coupled to a side of the redistribution layers opposite the first die.

14. The side-by-side integrated device package of claim 13, wherein a footprint of the heat spreader is larger than a footprint of the first die.

15. The side-by-side integrated device package of claim 13, further comprising a dielectric layer between the redistribution layers and the heat spreader.

16. The side-by-side integrated device package of claim 13, wherein the heat spreader comprises a bulk silicon block.

17. The side-by-side integrated device package of claim 13, wherein the heat spreader comprises a metal block.

18. A method comprising:
coupling a second side of a die to a set of redistribution layers such that a first side of the die that includes contacts of the die faces away from the redistribution layers;
electrically coupling first interconnect conductors to the redistribution layers along a first edge of the die; and
electrically coupling second interconnect conductors to the redistribution layers along a second edge of the die and external to the die, wherein the redistribution layers define a plurality of pairs of conductive paths between the first interconnect conductors and the second interconnect conductors.

19. The method of claim 18, further comprising:
electrically coupling the contacts of the die, the first interconnect conductors, and the second interconnect conductors to corresponding contacts of a package substrate; and
electrically coupling a second die to the package substrate such that:
a first communication channel between the die and the second die includes the first interconnect conductors, conductors of the redistribution layers, the second interconnect conductors, and first conductors of the package substrate; and
a second communication channel between the die and the second die includes second conductors of the package substrate.

20. The method of claim 18, further comprising coupling a heat spreader to a side of the redistribution layers opposite the die.
